(19) United States
(12) Patent Application Publication
(10) Pub. No.: US 2010/0117102 A1
(43) Pub. Date: May 13, 2010

(54) LIGHT EMITTING DIODES AND BACKLIGHT UNIT HAVING THE SAME

(75) Inventors: Ju-Young YOON, Seoul (KR); Eun-Jeong KANG, Cheonan-si (KR); Seok-Won KANG, Gwangju-si (KR)

Correspondence Address: CANTOR COLBURN, LLP, 20 Church Street, 22nd Floor, Hartford, CT, 06103, US

(73) Assignee: Samsung Electronics Co., Ltd., Suwon-si (KR)

(21) Appl. No.: 12/416,660

(22) Filed: Apr. 1, 2009

(30) Foreign Application Priority Data
Nov. 10, 2008 (KR) 10-2008-0111070

(51) Int. Cl. H01L 33/00; H05K 3/34

(52) U.S. Cl. 257/89; 257/98; 29/840; 257/E33.068

(57) ABSTRACT

The LED assembly has an LED chip, 2 via holes and 2 metal electrodes. The LED chip is attached to a front surface of the substrate. 2 via holes penetrate the front surface and a rear surface of the substrate opposite to the front surface, and 2 metal electrodes extend from the front surface to the rear surface through the via holes, respectively. The LED chip has an N-electrode and a P-electrode. The N-electrode and the P-electrode are electrically connected to the metal electrodes via wires, respectively, and the metal electrodes have exposed portions on the rear surface, respectively.

### FIELD OF INVENTION

The present invention relates to Light Emitting Diodes (LEDs), and more particularly, relates to Light Emitting Diodes (LEDs) used as a light source in a backlight unit of a Liquid Crystal Display (LCD) and a Backlight Unit having said LEDs.

### BACKGROUND OF THE INVENTION

An LCD is one type of a Flat Panel Display and displays images using liquid crystal material interposed between two insulating substrates. Since an LCD is light and thin and consumes little electric power compared to other types of display devices, it is widely used in various electronic devices, for instance, TVs, monitors, cell phones, and laptop computers.

Unlike other display devices such as a Cathode Ray Tube (CRT), and a Plasma Display Panel (PDP), a liquid crystal display panel used in an LCD cannot generate light by itself. Therefore, an LCD requires a separate light source which can provide the liquid display panel with light and a backlight unit including the light source.

Reviewing it in more detail referring to FIG. 1, an LCD device (1) includes an LCD panel (10) and a backlight unit (20). The LCD panel (10) adjusts the light through the LCD panel generated from the backlight unit (20) to display images.

The backlight unit (20) providing the LCD panel (10) with light may include a bottom chassis (21), a reflector (22), LEDs (240) as a light source disposed on a Flexible Printed Circuit (FPC) (23), a light guiding plate (25) to which the light generating surface of the LED is oriented, a mold frame (27), and an optical member (26). The optical member may include a diffuser sheet to uniformly scatter the light from the light source and a prism sheet to refract the light.

As a light source for a backlight unit, a Cold Cathode Fluorescent Lamp (CCFL), a Flat Fluorescent Lamp (FFL), and a Light Emitting Diode (LED) can be exemplified. Among these, since an LED is good in many aspects like power consumption, luminance and color reproducibility and does not cause environmental pollution, LEDs recently draw attention as a light source for various types of LCDs.

However, the conventional LED packages using lead frames are expensive and too large to be adopted in an LCD, especially in a small or middle size LCDs like those for a cellphone or a laptop computer of which a backlight unit is usually an edge-lit type and has a small space for LEDs.

A conventional LED package (240) is described in detail with reference to FIGS. 2 (a) and (b). A conventional LED package (240) comprises a substrate (241); lead frames (243) which are disposed on the substrate; an LED chip (242) comprising an N-electrode and a P-electrode (not shown) and mounted on the substrate (241); wires (244) which electrically connect the two electrodes to lead frames (243), respectively; a molding material (245) fixing and protecting the LED chip (242), the wire (244) and the lead frame (243) which molding material may work as a lens; a package housing (246) receiving the lead frames (243) and defining a space for the molding material (245). Substrate (241) and the housing (246) may be integrally formed, and be made of Poly-Phthal-Amid (PPA) or epoxy resin.

As can be seen from FIG. 2 (b), lead frames (243) extend laterally from the LED chip (242), and thus, the conventional LED packages (240) require a lot of space for the lead frames on the substrate. Thus, a small number of LED packages can be obtained from a unit length of the substrate, which causes the conventional LED packages to be expensive since the material of the substrate (241) is expensive.

Further, a conventional LED package (240) is mounted on an FPC (23) by soldering the lead frame (243) protruding from sides of the package housing (246). Therefore, a plurality of LED packages cannot be arranged close to each other to obtain the space for soldering, which limits the number of LED packages mounted on a unit length of an FPC.

### SUMMARY OF THE INVENTION

There are demands to use more LED packages and dispose LED packages more closely to each other. For example, the use of a combination of Red, Green, and Blue LEDs (RGB LED) is superior to the use of only white LEDs in color reproducibility; however, due to the low luminance of RGB LEDs compared to white LEDs, more use of LED chips are required to obtain sufficient luminance when using RGB LEDs. Further, since an LED is a point light source different from a CCFL, the problem of hot spots is inevitable. This problem can be solved by disposing LEDs more close to each other.

Such demands are even higher in a small or middle size LCD like a laptop computer or a cellphone because the small or middle size LCD itself is usually cheap and can allow only a small space for LED packages. However, the conventional LED packages with the foregoing features may not satisfy the demands, and thus, the use of the conventional LED package as a light source must be restrictive in a small or middle size LCDs.

To resolve the foregoing problems, in one embodiment of the present invention a cheap and small LED set is provided. Also, in other embodiments of the present invention, a method of mounting the cheap and small LED sets to help mount more LED sets in a unit length of an FPC in an edge-lit type backlight unit is provided.

One embodiment of the present invention provides an LED set which includes a substrate and an LED assembly. The LED assembly has an LED chip, 2 via holes and 2 metal electrodes. The LED chip is attached to a front surface of the substrate. 2 via holes penetrate the front surface and a rear surface of the substrate opposite to the front surface, and 2 metal electrodes extend from the front surface to the rear surface through the via holes, respectively. The LED chip includes an N-electrode and a P-electrode, the N-electrode and the P-electrode are electrically connected to the metal electrodes, respectively, and the metal electrodes have exposed portions on the rear surface, respectively.

In another embodiment of the present invention, a backlight unit having at least one optical member, a light guiding plate, a flexible printed circuit board, and an LED set is provided. The light guiding plate is disposed under the optical sheet and has an incident surface, and the flexible printed circuit board (FPC) is placed near the light guiding plate. The LED set includes a substrate and an LED assembly. The LED assembly has an LED chip, 2 via holes and 2 metal electrodes. The LED chip is attached to a front surface of the substrate. 2 via holes penetrate the front surface and a rear surface of the substrate opposite to the front surface, and 2 metal electrodes extend from the front surface to the rear surface through the via holes, respectively. The LED chip includes an N-electrode and a P-electrode, the N-electrode and the P-electrode are electrically connected to the metal electrodes, respectively, and the metal electrodes have exposed portions on the rear surface, respectively. The LED chip faces the incident surface of the light guiding plate, and the exposed portions of the metal electrodes are electrically connected to the FPC via soldering, respectively.

In another embodiment of the present invention, a method to mount the LED set according to the present invention includes putting an LED set having a substrate and an LED assembly on a Flexible Printed Circuit (FPC) so that an LED chip of the LED assembly faces a light guiding plate and soldering the LED set onto the FPC at a rear surface opposite the LED chip.

In another embodiment of the present invention, a method of manufacturing an LED set according to the present invention is provided. The method includes forming 2 via holes through a substrate, and positioning 2 metal electrodes in the via holes respectively so that portions of the metal electrodes are exposed on a rear surface of the substrate. The method further includes attaching an LED chip on a front surface of the substrate which is opposite the rear surface, and connecting a P-electrode and an N-electrode of the LED chip to the metal electrodes, respectively.

### BRIEF DESCRIPTIONS OF THE DRAWINGS

The above and other objects and advantages of the present invention will become more apparent by describing in detail exemplary embodiments thereof in reference to the attached drawings in which:

FIG. 1 is an exploded schematic view of an LCD module.

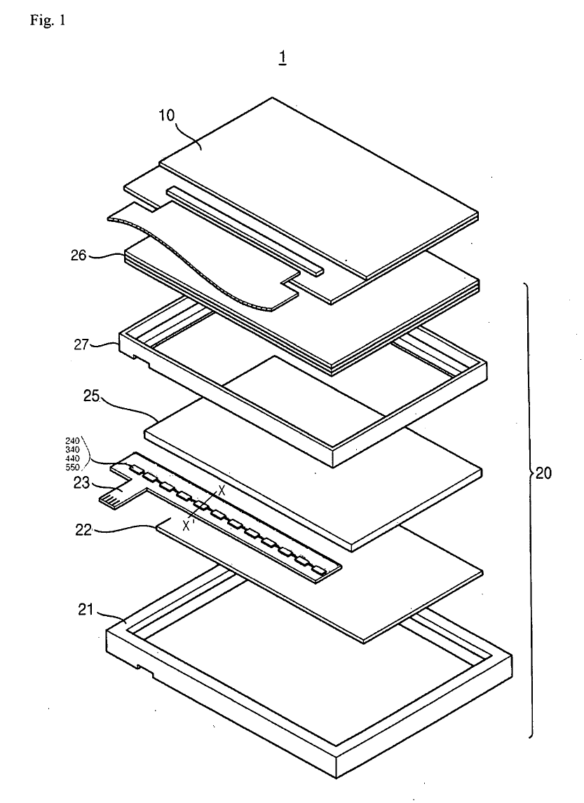

FIG. 2 (a) is a sectional view of an LED package, and FIG. 2 (b) is a plane view of an LED package.

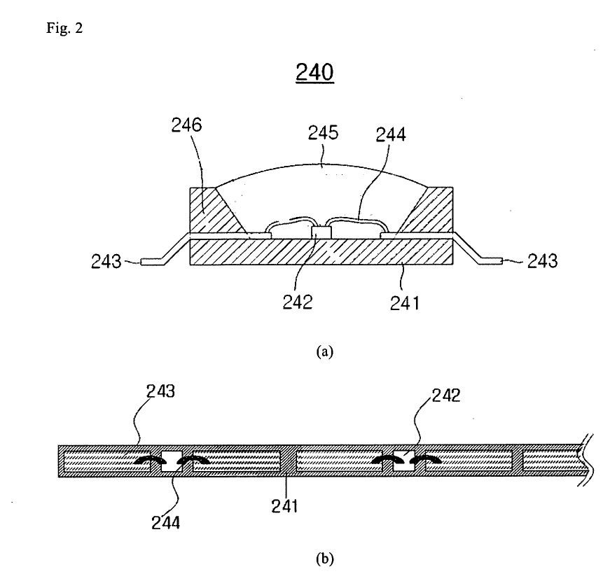

FIG. 3 is a sectional view of an LED set according to an embodiment of the present invention.

FIGS. 4 (a) and (b) are sectional views each of which shows an LED set according to an embodiment of the present invention.

FIG. 5 is a sectional view along the line X-X′ of FIG. 1 where an LED set according to an embodiment of the present invention is mounted on a FPC using the mounting method of the present invention.

### DETAILED DESCRIPTION

Hereinafter, embodiments of the present invention will be described in detail with reference to the drawings.

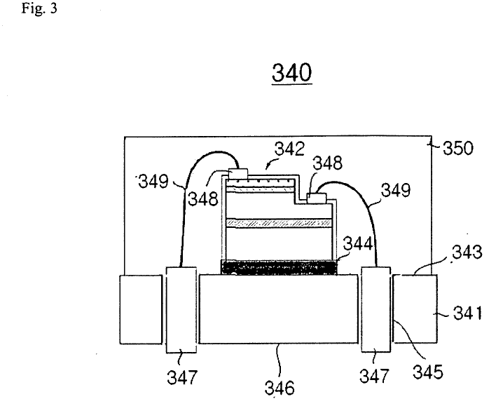

FIG. 3 shows an LED set according to one embodiment of the present invention. The LED set (340) comprises a substrate (341) and an LED assembly. The LED assembly includes an LED chip (342) attached on the front surface (343) of the substrate (341) by, for instance, using an adhesive (344) which may be an epoxy or silicon paste, 2 via holes (345) penetrating the front surface (343) and the rear surface (346) of the substrate (341), and 2 metal electrodes (347) which extend from the front surface (343) to the rear surface (346) through the via holes (345), respectively. The LED chip (342) has two electrodes (348) of which one is N-electrode and the other is P-electrode, and the electrodes (348) are electrically connected to the metal electrode (347), respectively. They may be connected via wires (349). A portion of each of the metal electrodes (348) is exposed on the rear surface (346) which portion is to be connected to FPC (23) on which the LED set (340) is to be mounted.

The LED set may include a lens (350) fixing and protecting the chip (342) and wires (349). The lens (350) may be made of transparent silicon material and the lens may be in various shapes such as a sphere, an oval, and a cube.

The LED chip (342) may include a white, red, green, and blue LED chip.

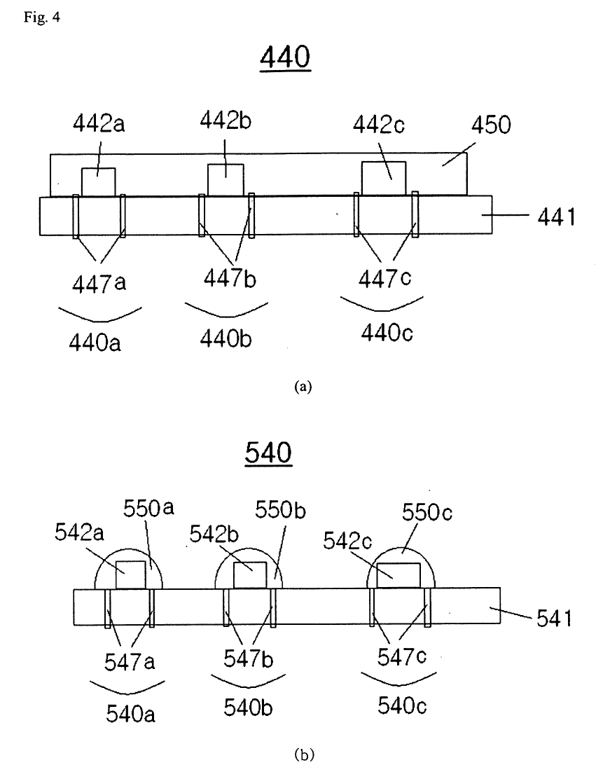

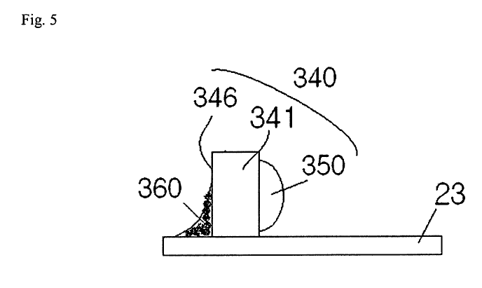

With reference to FIGS. 4 (a) and (b), another embodiment of the present invention is described. An LED set (440; 540) includes a substrate (441; 541) and a plurality of LED assemblies (440a, 440b, 440c; 540a, 540b, 540c). Each of the plurality of LED assemblies includes an LED chip (442a, 442b, 442c; 542a, 542b, 542c), two metal electrodes (447a, 447b, 447c; 547a, 547b, 547c), and wires (not shown) electrically connecting the electrodes (not shown) of the LCD chip (442a, 442b, 442c; 542a, 542b, 542c) and the metal electrodes (447a, 447b, 447c; 547a, 547b, 547c). In this type of LED set, since the width of an LED assembly is small and an LED assembly does not require a space at both sides for lead frames (243) to be bonded onto an FPC (23) as will be described in the following description referencing FIG. 5, each LED assembly (442a, 442b, 442c; 542a, 542b, 542c) can be placed close to each other. Therefore, in this LED set, more LED chips can be mounted in a small unit length of substrate compared to the conventional LED package having lead frames.

The LED set (440; 540) may include a plurality of LED assemblies. The LED set (440; 540) may include only white LED chips or may include Red, Green, and Blue Led chips.

The LED set (440) may include a lens which may be formed by molding material such as transparent silicon material, which lens (450) may be formed to cover all LED chips (442a, 442b, 442c). In another aspect of the invention, the LED set (540) may include a plurality of lenses (550a, 550b, 550c), each of the lenses covering one LED chip (542a, 542b, 542c). The lens (450; 550a, 550b, 550c) may be shaped as half-cylindrical where a section of the lens is semicircular, semielliptical, rectangular, or any other shape.

The substrate (341, 441, 541) may be made of, for example, FR-4 which is cheap in price and is capable of mechanically supporting LED assemblies on the substrate.

Now, in reference to FIG. 3 and FIG. 5, the method is explained to mount an LED set according to an embodiment of the present invention in an edge-lit type backlight unit (20) which is employed in a small or mid-sized LCD module. Unlike LED package (240), a metal electrode (347) has a portion exposed on the rear surface (346). In one embodiment of the present invention, the lens (350) faces the light guiding plate (25), and the exposed portion of a metal electrode (347) is soldered to a conductive pattern (not shown) on the FPC (23); that is, soldering is carried out at the rear surface (346). Accordingly, a plurality of LED sets (340) may be arranged closely side by side.

In addition, using the method according to the present invention allows the use of LED sets (450; 550) in which a plurality of LED assemblies (440a, 440b, 440c; 540a, 540b, 540c) are consecutively arranged.

Another embodiment of the present invention provides a backlight unit (20), that includes at least one optical member (26), a light guiding plate (25) disposed under the optical sheet (26) and having an incident surface, an FPC (23) placed near the light guiding plate (25), and an LED set (340). The LED chip (342) faces the incident surface of the light guiding plate (25), and exposed portions of the metal electrodes (347) are electrically connected to the FPC via soldering, respectively.

The backlight unit (20) may include a plurality of LED sets (340) including one LED chip (342) and/or at least one LED sets (440; 540) which has more than one LED chips (442a, 442b, 442c; 542a, 542b, 542c).

The LED chips (342; 442a, 442b, 442c; 542a, 542b, 542c) may include white, red, green and blue LED chips.

Another embodiment of the present invention provides a method to manufacture an LED set (340) according to the present invention. The method includes forming 2 via holes (345) through a substrate (341), positioning 2 metal electrodes (347) in the 2 via holes (345) respectively so that portions of the metal electrodes (347) are exposed on a rear surface (346) of the substrate (341), and attaching an LED chip (342) on a front surface (343) of the substrate (341) which is opposite the rear surface (346). The method further includes connecting the two electrodes (348) of the LED chip (342) to the metal electrodes (347), respectively.

Since the LED sets according to the embodiments of the present invention does not have lead frames protruded from the side of the LED sets, in a unit length of a substrate, more LED sets may be obtained than conventional LED packages, which will make the LED sets cheaper than the conventional LED packages. Further, also the use of cheap substrate like FR-4 may bring down the cost to manufacture the LED sets although other materials known to those skilled in the art may also be used. Meanwhile, as examined above, the LED sets and mounting method according to the present invention allow LED sets to be closely disposed and various modifications to the LED sets.

While the present invention has been described using some exemplary embodiments, it should be understood that the presentation of the embodiments is not to restrict the scope of the present invention into the embodiments, and that various changes, substitutions and alternations can be made without departing from the spirit and scope of the invention as defined by the appended claims.

What is claimed is:

1. An LED set comprising:
a substrate comprising:
a front surface, and
a rear surface opposite to the front surface; and
an LED assembly comprising:
an LED chip attached to the front surface of said substrate;
2 via holes penetrating said front surface and the rear surface of said substrate; and
metal electrodes extending from said front surface to the rear surface through said via holes, respectively;
wherein said LED chip comprises an N-electrode and an P-electrode, the N-electrode and the P-electrode are connected to said metal electrodes, respectively, and the metal electrodes have exposed portions on the rear surface, respectively.

2. The LED set of claim 1, wherein the LED assembly further comprises wires connecting the N-electrode and the P-electrode to said metal electrodes.

3. The LED set of claim 1 further comprising a lens disposed over the LED chip.

4. The LED set of claim 3, wherein said lens is made of transparent silicon material.

5. The LED set of claim 1, wherein the LED set comprises a plurality of LED assemblies.

6. The LED set of claim 5, wherein the LED assemblies comprise red, green and blue LED chips.

7. The LED set of claim 5 further comprising a lens covering all LED chips included in the plurality of LED assemblies.

8. The LED set of claim 5, wherein the lens is in a half-cylindrical shape where a section of the lens is semicircular, semielliptical, or rectangular.

9. The LED set of claim 5 further comprising a plurality of lenses covering each of the plurality of LED chips, respectively.

10. The LED set of claim 1, wherein the substrate is made of FR-4.

11. A backlight unit, comprising:
at least one optical member;
a light guiding plate disposed under the optical member and having an incident surface;
a flexible printed circuit board (FPC) placed near the light guiding plate; and
an LED set comprising:
a substrate;
an LED assembly comprising:
an LED chip attached to a front surface of said substrate;
2 via holes penetrating said front surface and the rear surface of said substrate; and
2 metal electrodes extending from said front surface to the rear surface through said via holes, respectively;
wherein said LED chip comprises an N-electrode and an P-electrode, the N-electrode and the P-electrode are connected to said metal electrodes, respectively, and the N-electrode and the P-electrode have exposed portions on the rear surface, respectively;
wherein the LED chip faces the incident surface of the light guiding plate, and exposed portions of the N-electrode and the P-electrode are connected to the FPC, respectively.

12. The LED set of claim 11, wherein the LED set comprises a plurality of LED assemblies.

13. The LED set of claim 12, wherein the LED assemblies comprise red, green and blue LED chips.

14. The LED set of claim 12, further comprising a lens covering all LED chips included in the plurality of LED assemblies.

15. The LED set of claim 12 further comprising a plurality of lenses covering each of the plurality of LED chips, respectively.

16. The LED set of claim 10, wherein the substrate is made of FR-4.

17. A method to mount an LED set, the method comprising:
positioning an LED set comprising a substrate and an LED assembly on a Flexible Printed Circuit (FPC) so that an LED chip included in the LED assembly faces a light guiding plate; and
soldering the LED set onto the FPC at a rear surface of the substrate opposite to the LED chip.

18. A method to manufacture an LED set, the method comprising:
forming 2 via holes penetrating a substrate;
fixing 2 metal electrodes in the 2 via holes respectively so that portions of the metal electrodes are exposed on a rear surface of the substrate;
attaching an LED chip comprising two electrodes on a front surface of the substrate; and
connecting the two electrodes of the LED chip to the 2 metal electrodes, respectively.
